(19) United States
(12) Patent Application Publication
(10) Pub. No.: US 2008/0268164 A1
(43) Pub. Date: Oct. 30, 2008

(54) Apparatuses and Methods for Cryogenic Cooling in Thermal Surface Treatment Processes

(75) Inventors: Matthew J. Thayer, Canton, GA (US); Zbigniew Zurecki, Macungie, PA (US)

Correspondence Address: AIR PRODUCTS AND CHEMICALS, INC.;PATENT DEPARTMENT, 7201 HAMILTON BOULEVARD, ALLENTOWN, PA, 181951501, US

(73) Assignee: Air Products and Chemicals, Inc., Allentown, PA (US)

(21) Appl. No.: 12/106,565

(22) Filed: Apr. 21, 2008

Related U.S. Application Data
(60) Provisional application No. 60/926,351, filed on Apr. 26, 2007.

(51) Int. Cl. C23C 16/00; B05D 1/08; C23C 14/28

(52) U.S. Cl. 427/446; 427/255.28; 427/595; 118/715

(57) ABSTRACT

Apparatuses and methods for preventing the degradation of one or more mask materials during a thermal surface treatment process of a substrate having the steps of mounting at least one mask comprising one or more mask materials onto a substrate; thermally surface treating a surface of the substrate which increases the temperature of the substrate; and cooling the one or more mask materials with cryogenic fluid from at least one cooling means directed at the substrate.

### CROSS-REFERENCE TO RELATED APPLICATIONS

This patent application claims the benefit of provisional patent application U.S. Ser. No. 60/926,351, entitled “Apparatuses and methods for cryogenic cooling in thermal spray coating operations with or without the use of masks” filed Apr. 26, 2007, incorporated herein by reference.

### BACKGROUND OF THE INVENTION

Thermal spraying of parts is a well-known technique for applying thick and durable metallic or ceramic coatings on the part, to provide a thermal barrier, improve surface hardness and wear resistance, enhance corrosion resistance, or alter other properties of the original surface. The main thermal spray coating processes include thermal plasma, high-velocity oxy-fuel (HVOF), arc-spraying and flame spraying.

The spraying is widely used for critical wear parts like landing gear, bearing races, valves and turbine components. The process generally involves deposition of fully or partially molten metal, composite, polymer, or ceramic droplets, propelled from a gun or torch onto the workpiece. Air cooling is frequently employed to cool the part during the spraying process, but has been proven insufficient in the case of high-throughput, production operations and, consequently, inter-pass cooling breaks are required to cool down the part effectively by periodically moving the gun away from the part. Such interrupted spray coating mode results in time and coating material losses and may contribute thermal degradation of substrate material and other materials contacting the substrate, e.g. mounting, holding, and surface masking materials.

It is important to mask certain areas of the part, where the coating might not be needed, for some spray coating applications. The coating of these areas might be undesirable, might interfere with the mechanical working of the component, might be unneeded, or might be uneconomical. In these cases, it is critical to provide an effective barrier to coating for these areas. Metal plates (shadow plates) are often used to protect these areas, as are masking tapes.

The desirable aspects of a masking tape are flexibility of tape, ease of application and removal, quick clean-up and extended useful life. There is a wide variety of masking tapes available today with materials of construction ranging from fiberglass and metals to polymer and silicone rubbers. Examples of mask materials are disclosed in U.S. Pat. Nos. 5,508,097; 5,691,018; 5,112,683; and 5,322,727. However, most of the masking tapes available today fail to provide all the desirable aspects. The metal tapes, for example, are usually difficult to make and install, while the fiberglass and polymer tapes are easy to install, but difficult to remove and require extensive post-thermal-treatment cleaning. Inadequacy of air cooling and build-up of temperature in the mask are the primary reasons for tape degradation, e.g. thermal decomposition, hardening, or embrittlement, as shown in FIG. 1.

### SUMMARY OF THE INVENTION

This invention provides a method for preventing the degradation of one or more mask materials during a thermal surface treatment process of a substrate comprising the steps of: mounting at least one mask comprising one or more mask materials onto a substrate; thermally surface treating a surface of the substrate which increases the temperature of the substrate; and cooling the one or more mask materials with cryogenic fluid from at least one cooling means directed at the substrate. Another method of the invention includes the step of cooling the substrate to a temperature not exceeding the degradation temperature of the one or more mask materials adjacent to said substrate. The cooling step may be continuous or intermittent to the mask. The cooling means may be a nozzle or header or other like device for directing a coolant at a part. The substrate and/or the cooling means and/or the thermal treatment means may be individually and/or independently and/or simultaneously moved or rotated and/or may move or rotate as a single unit (for example when mounted on a single robot) during the method.

Also provided are apparatuses for performing the thermal surface treatment method comprising a thermal treatment means and at least one cooling means.

The method and apparatuses of this invention are useful in preventing the degradation of one or mask materials mounted on a substrate while thermally surface treating the substrate. Previous known processes have failed to prevent the degradation of the mask.

### BRIEF DESCRIPTION OF SEVERAL VIEWS OF THE DRAWINGS

FIG. 1 shows thermal spray process steps of the prior art with insufficient cooling.

FIG. 2 shows one embodiment of the thermal spray process steps of this invention.

FIG. 3 shows one embodiment of the thermal surface treatment apparatus and process of this invention.

FIG. 4 shows another embodiment of the thermal surface treatment apparatus and process of this invention.

FIG. 5 shows another embodiment of the thermal surface treatment apparatus and process of this invention.

FIG. 6 shows another embodiment of the thermal surface treatment apparatus and process of this invention.

FIG. 7 shows another embodiment of the thermal surface treatment apparatus and process of this invention.

### DETAILED DESCRIPTION OF THE INVENTION

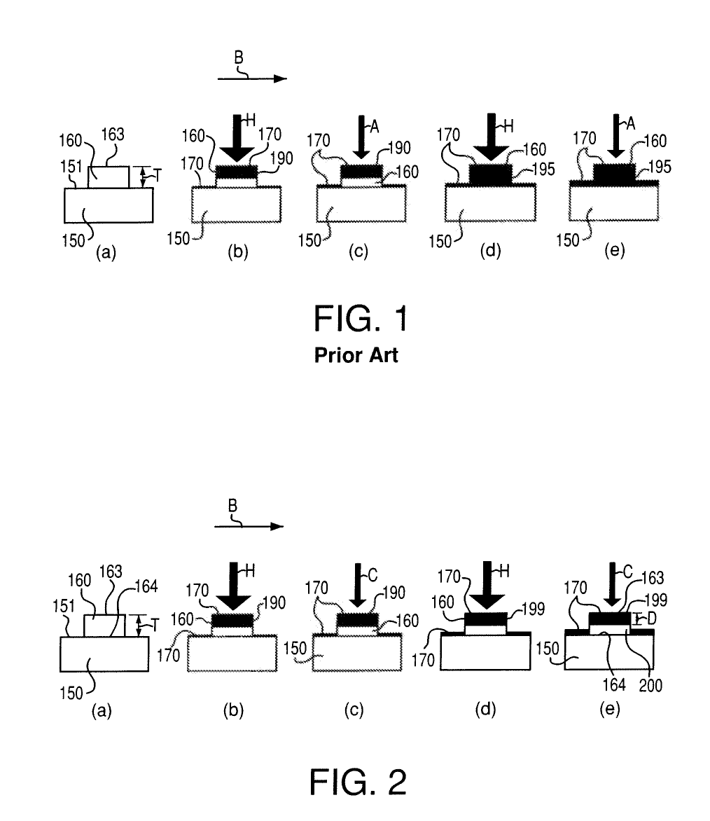

FIG. 1 shows the sequence of the degradation of a mask when used in a thermal spray process with insufficient cooling, but will be useful in understanding this invention. In the first process step shown in (a) a layer or layers of temperature-sensitive masking material, that is, the mask 160 having a thickness T has been mounted onto a surface 151 substrate 150 in preparation for receiving thermal spray. In the second process step shown in step (b) a thermal surface treatment means which may be and will be referred to as a thermal spray gun shown as arrow H deposits material 170 upon the surface 151 of the substrate 150 and surface 163 of the mask 160 as the gun traverses in the direction shown by arrow B. The material 170 impacts the substrate at high temperatures and velocity (high energy). The heat and energy of the deposited material 170 causes the mask to become heated and embrittled as shown as the darkened area 190 in figure (b). In step (c), the surface 151 of the substrate 150 and/or the coating or deposited material 170 and/or the mask 160 are air cooled as shown by the arrow labeled A which partially cools the area 190. In step (d), the gun H again passes over the same area of the substrate and the mask 160 depositing additional coating material 170 on the surfaces of the substrate 150 and the mask 160 (onto the coating applied in the first pass). In step (d), the heat and energy of the deposited material 170 causes the entire mask 160 to become heated and embrittled as shown as the larger darkened area 195 which includes the darkened area 190 shown in steps (b) and (c). Volume 195 of the mask 160 includes the entire thickness T of the mask where it was treated. The embrittlement of the mask may cause the mask to detach from the substrate, and/or to crumble during the coating process, and/or to fail to remove from the substrate after the thermal treatment (spraying) process.

For some embodiments of the present invention the mask degradation issue is resolved by employing a novel cryogenic cooling method. Using the new cooling process, the mask can be applied and removed quickly and/or easily, and in some cases, can be re-used, thus saving time and costs associated with the use of the mask.

The current invention involves cryogenic cooling of the substrate part and the mask thereon or thereover, during the thermal surface treatment or thermal spray coating process. Alternatively, only the mask is cooled cryogenically during the spraying process, while the substrate part is cooled by some other means, e.g. directing compressed air, water, carbon dioxide or any other noncryogenic coolant or noncryogenic cooling means at the part. Alternatively, the mask and substrate may be cooled separately by more than one cryogenic spraying means directed at the substrate and each of the mask(s) on the substrate. Alternatively, one or more masks on a substrate may be cooled by at least one cryogenic spraying means directed at the one or more masks, and the substrate may optionally be cooled by cryogenic means or other cooling means. The cooling means may be stationary or movable by robots or other motorized and optionally programmable or controllable moving means.

The masks useful in the present inventions may be tapes, panels or putty-like materials or any other material types known in the art and may comprise fiberglass, metals, polymers and silicone rubbers or mixtures of layers of these materials or any materials known to be useful for making masks useful in thermal (spray coating) processes, including the materials disclosed in U.S. Pat. Nos. 5,508,097; 5,691,018; 5,112,683; and 5,322,727, incorporated herein by reference.

The indefinite articles “a” and “an” as used herein mean one or more when applied to any feature in embodiments of the present invention described in the specification and claims. The use of “a” and “an” does not limit the meaning to a single feature unless such a limit is specifically stated. The definite article “the” preceding singular or plural nouns or noun phrases denotes a particular specified feature or particular specified features and may have a singular or plural connotation depending upon the context in which it is used. The adjective “any” means one, some, or all indiscriminately of whatever quantity. The term “and/or” placed between a first entity and a second entity means one of (1) the first entity, (2) the second entity, and (3) the first entity and the second entity.

The term “mounted” will be used to describe the positioning of the mask on, over, or onto the substrate. The term mounted is not limiting and includes adhering, fixing, laying over, paining on, contacting, attaching, fitting, bolting on, clamping, or any other mechanical or chemical attachment means.

The cryogenic cooling medium or cryogenic fluid useful in this invention can be any cryogenic fluid or mixture of cryogenic fluids, such as, nitrogen, helium, carbon dioxide or argon, but in the preferred embodiment, nitrogen is used. The cryogenic fluid may be in gas (vapor), liquid, or gas-liquid mixture and may, optionally, contain fine solid particles. The particles may consist of ice which melts and/or evaporates in the ambient conditions of 1 atmosphere pressure and room temperature. The particles may also consist of materials that are solid in the ambient conditions, e.g. salt crystals or ceramic oxides. The cryogenic fluid is jetted from a cryogenic nozzle toward the substrate and masking material and if, in addition to the gas phase, this jet contains liquid droplets or solid particles, then it is sometimes referred to as a cryogenic spray. A cryogenic fluid is one that is at a temperature below minus 150 Celsius degrees, i.e. a temperature low enough to rapidly cool the surfaces exposed to it. Higher coolant fluid temperatures may be used; however, as the temperature of the coolant fluid increases, it's effectiveness as a coolant decreases.

The thermal surface treatment processes are any thermal treatment processes used to modify the surface of a substrate. The thermal surface treatment processes may be thermal spray processes that include thermal plasma, high-velocity oxy-fuel (HVOF), arc-spraying and flame spraying. The processes may, also, involve chemical and/or physical vapor deposition methods as well as flash-lamp treatment or ultraviolet lamp, radiative curing of substrate surface. The thermal surface treatment processes are processes that usually heat a substrate in at least a small portion of the substrate. The heating of the substrate may or may not be the desired effect of the thermal surface treatment process. For the thermal treatment (spray coating) processes, the substrate which may also be referred to as parts, may comprise metals such as iron, nickel, aluminum, titanium, and copper and their alloys and composites with ceramic and organic (polymer) materials, oxide, nitride, carbide, and complex ceramics and their composites with metals and polymers, carbon and epoxy composites, polymeric materials, glasses, silicon and silicon compounds, microporous, porous and foamy materials, both inorganic and organic, welded and brazed or soldered structures, and the like. For thermal spray coating processes, the typical coating materials include the following: metals, ceramics, metal matrix and ceramic matrix composites, polymers and polymer matrix composites. The most popular materials from these groups are carbide hardfacing coatings such as WC-Co or Cr3C2, Al2O3 and ZrO2 based thermal barrier coatings, Ni, Ni—Al and Ni—Cr bond coats, NiAl, FeAl, and MoSi2 intermetallic coatings, MCrAlY oxidation protection superalloy coatings, Ta-coatings against acid corrosion and for glass lining repair, general purpose Al and Zn coatings against aqueous corrosion, Al-polymer abrasive coatings for sealing turbine and pump/compressor blades, Cu coatings for electric conductivity and decorative purposes and well as diverse nylon and copolymer coatings for solvent-free deposition.

The term “directed” means applied, forced, sprayed, jetted, aimed, blown and the like.

One embodiment of this invention is shown in FIG. 2. The same components shown in FIG. 2 and shown in FIG. 1 are labeled by the same numbers and letters. In the first process step shown in (a) a mask 160 has been mounted onto a surface 151 of the substrate 150 in preparation for receiving a thermal surface treatment. In the second process step shown in step (b) a thermal treatment means, for example, a spray gun, shown as arrow H deposits material 170 at high temperatures and speeds (high energy) upon the surface 151 of the substrate 150 and the surface 163 of the mask 160 as the gun traverses in the direction shown by arrow B. The heat and energy of the deposited material 170 causes the mask to become heated and in many cases embrittled as shown as the darkened area 190 in figure (b). In step (c), the substrate 150 and/or the coating material 170 and/or the mask 160 are cooled by a cryogenic fluid sprayed or otherwise applied onto the mask as shown by the arrow labeled C which cools the mask 160 in at least the heated and/or embrittled area 190. In step (d), the gun H again passes over the same area of the substrate 150 and the mask 160 depositing additional material 170 on the substrate 150 and the mask 160. Since the mask 160 was cooled to a lower temperature than in the process shown in FIG. 1, due to the application of the cryogenic fluid in the process shown in FIG. 2, the heat and energy of the deposited material 170 applied in step (d) of FIG. 2 causes the mask 160 to only become heated and/or embrittled in volume 199. Volume 199 may be the same, more or less than the heated and/or embrittled volume 190 of the first pass of the thermal spray in step (b). The depth D of the volume 199 is less than the entire thickness T of the mask. The heated and/or embrittled volume 199, in subsequent passes of the thermal spray gun, if any (although not shown) in the process of this invention may have a depth that is the same, more or less than the embrittled volume 190 of the first pass of the thermal spray in step (b); however, the final depth D of the embrittled volume will be less than the entire thickness T of the mask. In this way the mask will not detach from the substrate, and/or detrimentally crumble during the coating process, and/or fail to remove from the substrate after the thermal spraying process. Use of the cooling process and apparatus of this invention provides instantaneous or near instantaneous cooling of the deposited material 170 on the mask and the mask 160 beneath, avoiding heat build-up and preventing the heat of the just-deposited, solidifying coating material from migrating to the bottom surface 164 of the mask. As a result, the bottom surface 164 of the mask 160 stays undegraded. The undegraded volume 200 of the mask is located adjacent to substrate 150 and furthermost from the top surface 163 of the mask 160 which receives the deposited material 170 thereon. The volume 200 includes the bottom surface 164 of the mask 160 contacting the surface 151 of the substrate 150. Undegraded mask allows for quick removal of the mask after the thermal treatment (spray operation), for example, with a putty knife, and/or the mask will leave a clean residue-free substrate surface after removal and/or the undegraded mask can be re-used several times before the end of its useful life.

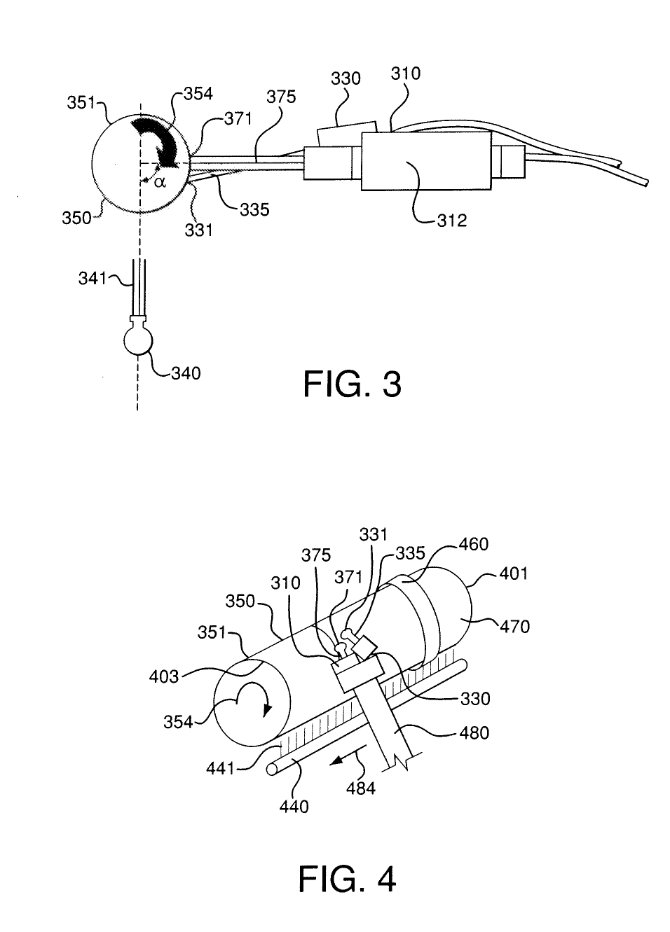

Different embodiments of the apparatuses and processes of this invention are shown in FIGS. 3, 4, 5, 6 and 7. In the embodiment shown in FIG. 3, a cryogenic fluid jet nozzle 330, which is the a first cooling means, is shown adjacent to the side of the thermal treatment means 310 opposite to the side 312 visible in FIG. 3. Thermal treatment means is a spray gun 310. The cryogenic nozzle 330 and the thermal spray gun 310 may be mounted separately onto stationary supports (not shown) or onto individual robot arms (not shown) or both may be mounted onto a single robot arm (as shown in FIG. 4) or the cryogenic nozzle may be mounted onto the spray gun 310 which is mounted onto a robot arm or either or both may be mounted onto motorized movement means, which may be programmable or otherwise controllable. The substrate 350, that is to receive the coating material 375 that exits the thermal spray gun 310, rotates in the direction shown by the arrow 354 while mounted or otherwise connected to a lathe or other motor driven rotating device (not shown). FIG. 3 shows the application of a coating material 375, such as an HVOF spray containing tungsten carbide/cobalt (WC/Co) that is being cooled as it is applied to the surface 351 of the substrate 350 with a cryogenic fluid vapor jet 330 exiting or issued from the nozzle mounted on the gun 310. The cryogenic fluid may contact the surface 351 of the substrate 350 or the deposited material (not shown) over the substrate 350, or if present over a mask (not present in the embodiment shown in FIG. 3). The cryogenic fluid 335 sprayed onto the substrate trails the coating material 375 being sprayed onto the substrate 350. (The expression “directed (or sprayed or applied onto the substrate” means onto the surface of any one of the following unless otherwise specified: onto a yet to be thermally treated, for example, an uncoated surface of the substrate; onto a coating already on a substrate; onto a mask over a substrate; or onto a coating on a mask on a substrate.) The expression “thermally treating the substrate” means thermally treating the surface of any one of the following unless otherwise specified: onto a clean substrate; onto a coating already on a substrate; onto a mask over a substrate; or onto a coating on a mask on a substrate.) In the preferred embodiment, background or additional cooling involving either cryogenic fluid or standard air cooling or other coolant can be employed to maximize the cooling effect. As shown in FIG. 3, the additional cooling means is a cryogenic fluid or cryovapor cooling nozzle 340 which directs a cryogenic fluid jet 341 at the substrate 350. Alternatively an air header could be used as the additional cooling means.

FIG. 4 shows a similar embodiment to that shown in FIG. 3, except that it shows a robot arm 480 to which the thermal treatment means, that is, a thermal spray gun 310 and the cooling means, that is, a cryogenic nozzle 330 are mounted. The thermal treatment means and the cooling means move simultaneously. It also shows arrow 484 which indicates the direction that the robot arm 480 is moving while the substrate is thermally treated. Further, FIG. 4 shows the deposited coating 470 over a portion of the surfaces 351 of the substrate 350. The process is shown about midway through the first pass over the substrate by the traversing gun 310 and nozzle 330. The thermal treatment process began at end 401 of the substrate and is progressing towards the opposite end 403 of the substrate. When the gun 310 reaches end 403, the process may be complete or one or more additional passes of the gun 310 and the nozzle 330 over the surface of the substrate may be repeated for a multi-pass process. As shown in FIG. 4, the mask 460 has been coated with the deposited coating 470 and has been cooled by the application of the cryogenic fluid exiting the nozzle 330 in the first pass of the gun 310 and the nozzle 330 over the mask 460. The cryogenic fluid, as shown, is sprayed onto and contacts the surface of the substrate 350 at location 331 so that it follows the hot area or a hot spray impact zone 371 of the deposited material 470. In FIG. 4, an additional cooling means 440 is provided. As shown the additional cooling means is an air header 440 which directs cooling air 441 at the substrate. The term header indicates an array of nozzles with or without the option of individual adjustment, a manifold with a series of orifices, a linear (knife) nozzle or nozzles, a straight pipe or a looped tubing with a series of holes, and all other devices that could be used to discharge convectively cooling fluids toward the substrate and mask surfaces.

As shown in FIG. 4, the first cooling means that provides cryogenic fluid (cryogenic fluid nozzle 330) provides cooling to the substrate and/or mask at the trailing side of the material sprayed 375 from the thermal spray gun 310, optionally while background (additional) cooling is provided from an additional cooling means, which can be a one or more nozzles or a header directed at the substrate, spraying or jetting either air (as shown in FIG. 4) or cryogenic fluid (as shown in FIG. 3) or any other cooling fluid. The cooling air can be provided by, for example, a shop air header fed from air compressor (not shown). The cryogenic nozzle provides for a directed stream of cryogenic fluid. As shown in the FIGS. 3 and 4, for cylindrical or other shaped substrates, it is preferred that the cryogenic spray (jet) is not directed at the same point as the thermal spray nozzle but is offset from and behind the spray from the thermal spray nozzle at the substrate. In this method, the cryogenic spray cools the surface of the substrate after it has received the thermal spray coating. Both the thermal spray nozzle and the cryogenic spray are directed substantially perpendicularly to the surface of the substrate receiving and having received the thermal spray, respectively, in order to maximize cooling efficiency. Further, the additional cooling means, for example, cryogenic fluid or air for cooling from the optional additional source, for example, bank of nozzles aimed at the part, should be directed substantially perpendicularly to the surface of the substrate nearest the additional cooling means. Additionally, it is presently believed, for cylindrical or similarly shaped substrates and in the embodiments shown in FIGS. 3 and 4, that it is desirable to locate the thermal surface treatment means (e.g spray gun 310) and the additional cooling means (e.g. nozzle or header 340) at an angle α (see FIG. 3) less than 330 degrees away, or less than 140 degrees away, or less than 110 degrees away, or less than 100 degrees away or less than 90 degrees away from each other around the circumference of the cylindrical or similarly-shaped substrate so that the surface of the cylindrically or similarly-shaped substrate that receives the thermal surface treatment (e.g spray coating) receives the additional cooling shortly after receiving the thermal surface treatment and the cooling from the first cooling means (e.g. the cryogenic jet nozzle). Also, it is presently believed that it is desirable to space the additional cooling means (for example, the bank of nozzles) and the thermal treatment means (for example, spray gun) at an angle α no closer than 30 degrees apart. In alternative embodiments, it is presently believed that the additional cooling means and the thermal treatment means should be no closer than 30 degrees apart and no further away than 100 degrees, or 110 degrees or 140 degrees from each other around the circumference of the cylindrical substrate.

In one embodiment of the apparatus of the invention, like the one shown in FIG. 4, the air flows at a pressure of 100-125 psig (0.69 MPa-0.86 MPa) through the air header which is located 2-4 inches (0.05 m-0.10 m) away from the surface of the part. The cryogenic fluid (for example, nitrogen) nozzle exit is 3-4 inches (0.076 m-0.10 m) away from the surface of the substrate and the spray gun nozzle exit is approximately 9.5 inches (0.24 m) from the substrate surface. The total mass flowrate of the cryogenic nitrogen spray on the part may be from 2 to 25 lbs/minute (0.9 kg/minute-11.3 kg/minute).

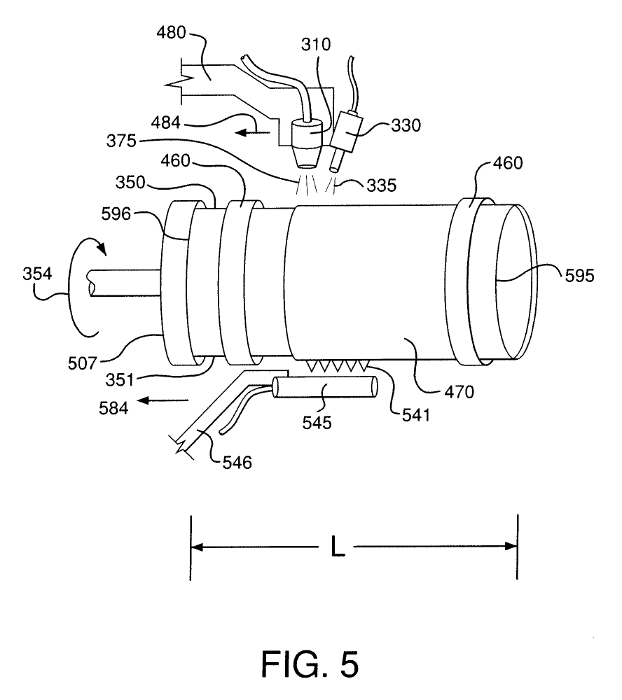

FIG. 5 shows an embodiment of the apparatus and process of this invention similar to the ones shown in FIGS. 3 and 4. The embodiment shown in FIG. 5 differs in that it shows a substrate 350 covered by multiple (two) masks, each labeled 460. Similar to that shown in FIG. 4, thermal treatment means 310 and first cooling means are both carried by robot arm 480. FIG. 5 shows a mounting bracket 507 that is attached to a motor (not shown) that rotates the mounting bracket and the substrate in the direction shown by arrow 354. FIG. 5 additionally shows an additional cooling means 545 that is mounted on a robot arm 546. The additional cooling means can direct air, cryogenic fluid or other coolant 541 onto the part. The robot 546 and robot 480 are programmed and controlled by controlling means (not shown) for example, a computer, to move simultaneously, traverse the substrate at the same speed or to otherwise move in a controlled fashion in the same direction with similar timing or near-similar timing from one end 595 of the substrate to the other end 598 of the substrate along the substrate's length L. The robots 480 and 546 move in the direction labeled by arrows 484 and 584, respectively. The movement of the additional cooling means in the same direction as and preferably at the same rate as the thermal surface treatment means, provides the additional coolant where the substrate is hottest along its length L. In this embodiment, the additional cooling means may be a fraction of the length of the substrate, for example the additional cooling means may be less than half of the length of the substrate.

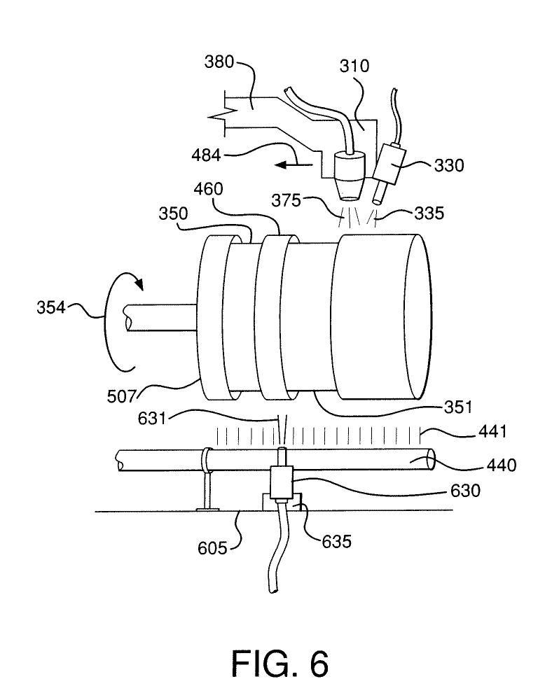

FIG. 6 shows another embodiment of the apparatus and process of this invention. FIG. 6 is similar to FIG. 5 except that it shows a single mask 460 attached to the substrate 350, and two additional cooling means 440 and 630. One additional cooling means is a stationary air header 440 directing air 441 at the substrate 350; the second additional cooling means is a stationary cryogenic fluid nozzle 630 directing cryogenic fluid 631 at the mask 460. The stationary nozzle 630 is shown mounted to the shop floor 605 via mounting bracket 635. For embodiments of this invention in which the masks are more intensly or more frequently heated by the thermal surface treatment means, it may be beneficial to continuously cool the mask via a cooling means that is continuously or near continuously directed at the mask during the thermal treatment process. In the embodiment shown in FIG. 6, the substrate is relatively short in length (as compared to the embodiment shown in FIG. 5) and if the substrate is to be thermally treated in multiple passes, the mask will be heated multiple times with a relatively shorter time to cool (again as compared to the embodiment shown in FIG. 5 assuming the process is operating similarly, at similar treatment rates); therefore, continuously cooling the mask during the thermal treatment process via the application of cryogenic fluid from the stationary cryogenic fluid nozzle will prevent the degradation of the mask although it will be heated more frequently (at a higher heating rate) than the embodiment shown in FIG. 5.

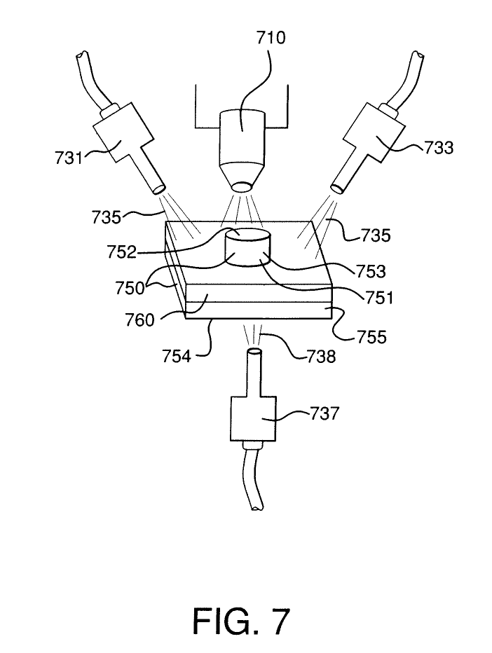

FIG. 7 shows another embodiment of the invention for a stationary substrate. The substrate 750 only has a small portion 751, consisting of top surface 752 and 753, that is to be treated by the thermal surface treatment means 710. The thermal surface treatment means is mounted on a robot (not shown) that swivels and rotates the thermal treatment means so that the surfaces of the portion 751, including the top surface 752 and the side surface 753 are treated, for example, coated by a thermal spray coating process. The larger portion 755 of the substrate 750 is not to receive any thermal treatment and is therefore protected by a mask 760. The mask is mounted onto the substrate 750. During the thermal surface treatment process, the mask 760 may be cooled via one or more cooling means. The cooling means shown in FIG. 7 include two cryogenic fluid nozzles 731 and 733 which each spray cryogenic fluid 735 at the mask 760. The cooling means 731 and 733 cool the mask 760 to prevent the mask from degrading. One or more of the cryogenic fluid nozzles 731 and 733 may be movable, that is mounted on a robot or other movable means, or they may both be stationary. The cryogenic fluid 735 may be supplied continuously, near-continuously or intermittently from one or both nozzles. Also shown in FIG. 7, is optional cooling nozzle 737. The cooling nozzle 737 is mounted facing the bottom surface 754 of the substrate and can direct or apply coolant, either a cryogenic fluid or air at the bottom surface 754 of the substrate 750. The bottom surface 754 of the substrate is a surface of the substrate 754 that will not be treated by the thermal surface treatment means 710. The coolant 738 directed at the bottom surface of the substrate 754 indirectly cools the surface of the portion 751 of the substrate which is thermally surface treated and the surfaces (not shown) of the substrate contacting the mask.

For other stationary substrates, or non-symmetrically shaped substrates, non-cylindrical substrates, the cryogenic nozzle may be mounted onto the spray gun to provide cooling to the substrate and/or mask, preferably at the trailing edge of the spray, as described above, and optionally while additional (background) cooling is provided through a nozzle or header (bank of nozzles) aimed at the part, jetting either air or cryogen or other coolant. The additional bank of cryogenic nozzles may be aimed at the top and/or the bottom surface of the substrate as shown in the FIGS. 3-7 herein and in US Ser. No. 11/389,308 previously incorporated herein by reference. Cooling the back surface of the substrate part (a surface of the substrate that is not subject to the thermal surface treatment, for example, spray coating) is acceptable as shown for FIG. 7.

For thermal surface treatment methods using a mask, the cooling during the thermal surface treatment process may follow one, two or all three of the following steps/learnings: First, the substrate surface temperature contacting the mask should be maintained at a temperature lower than the degradation temperature of the mask material or at least of the mask material in the layer of the mask contacting the substrate if the mask consists of more than one layer of material. For example, for a mask material consisting of silicone compound-mask or Si rubber comprising polyorganosiloxanes with amorphose silica and auxiliaries, available from Aerospace International Materials (AIM), the degradation of those materials does not take place until the substrate temperature exceeds 150 degrees C. (300 degrees F.). Cryogenic cooling is effective in assuring that the substrate temperatures are maintained below this limit, but other substrate cooling methods involving for example air, carbon dioxide, or water may be employed here as well alone or with the cryogenic cooling to maintain the substrate temperature below the degradation temperature of the mask material adjacent to or contacting the substrate.

Secondly, if the mask is cryogenically cooled along with the substrate using a moving cryogenic nozzle, intermittently, as shown in FIGS. 3, 4, 5, and 6 there exists a certain minimum mask thickness below which the degradation cannot be avoided. This minimum mask thickness depends on (1) the substrate temperature, (2) the mask material conductivity, (3) the intensity of heating by the thermal surface treatment means, for example, the spray-coating gun, (4) the intensity of the cooling means, for example, the cryogenic cooling jet, and (5) the delay between the hot spray from the thermal surface treatment means, for example, the spray gun, and the cold spray from the cooling means, for example the cryogenic cooling jet that the mask experiences. The minimum thickness is the thickness of the top (spray-facing) layer of the mask material that is degraded during a single pass of the thermal surface treatment means, for example, spray gun pass unless continuous cryogenic cooling is applied to the mask. Thirdly, if the mask is cryogenically cooled in a non-stop (continuous) mode during the thermal surface treatment process, irrespective of the actual position of the spray-coating gun, the minimum thickness of the mask is less than if the cooling is only applied to the mask intermittently.

The application of a cryogenic fluid enhances cooling and prevents heat build-up in the apparatus and the mask, preventing the progression of the degradation of the mask from the top, deeper into the bulk of the mask material (see FIG. 2). An infra-red temperature feedback system may also be used in the apparatus and process of this invention which controls the cryogenic fluid flowrate, allowing just enough cooling to maintain the part and mask within a pre-defined, tight temperature range and preventing unnecessary overcooling of the part and mask and wasting the cryogenic fluid. Examples of apparatuses and process that can be used in this process include those disclosed in Zurecki, U.S. patent Ser. No. 11/389,308, filed Mar. 27, 2006 and incorporated herein by reference, and provisional patent application, Zurecki, U.S. Patent Ser. No. 60/851,197, filed Oct. 12, 2006, incorporated herein by reference.

The apparatus of the invention and the thermal surface treatment process of this invention that provides cryogenic cooling of the substrate has been shown to eliminate the inter-pass cooling breaks as well as increase the coating material deposition efficiency as shown in the table below. The deposition efficiency is defined here as fraction of sprayed material that is recovered on the substrate surface in form of a coating.

Our masking and deposition efficiency tests involved spray-coating of steel pipes with WC-Co coating material using HVOF gun. The test system was configured as shown in FIG. 4. While all test parameters were kept the same during testing, three different methods of cooling were used: [1] cooling with compressed air discharged from a stationary air header 440 (conventional method), [2] cooling with compressed air discharged from stationary air header 440 combined with cooling by jet of cryogenic nitrogen 335 issued by nozzle 330 trailing HVOF gun 310, and [3] ambient air cooling, i.e. a natural cooling without the use of compressed air or cryogen. The 1^{st} cooling method required the use of cooling breaks between the HVOF gun passes over the workpiece 350, and in order to keep the workpiece temperature below 300° F. (150° C.), the time-length of cooling breaks was equal to the time-length of coating passes. The 2^{nd} cooling method did not required any cooling breaks and maintained the substrate temperature below 300° F. (150° C.) all the time. The coating work was, thus, completed in half a time. The 3^{rd} cooling method was unable to keep substrate temperature below 300° F. (150° C.) even when the cooling breaks were 10-times longer than the spraying passes and, eventually, the coating was deposited with the substrate temperature exceeding 575° F. (302° C.). The strip of flexible, self-adhesive silicon rubber mask 460 applied to each pipe tested, survived only the 2^{nd} test and was later reused in other masking work. The strips used in the 1^{st} and the 3^{rd} test did not survive, and their residue on the substrate surface had to be ground-off, which is a highly undesired cleaning procedure.

The test coated pipes were cross-sectioned and metallographically examined. The density of the WC-Co coatings produced with the three cooling methods was within the acceptable limits, with the cryo-cooled coating density being the highest and the ambient air cooled coating being the lowest. Also the hardness and carbon retention was found to be highest in the case of the cryocooled coating and the lowest in the case of ambient air cooled coating. The substrate steel after the ambient air cooling test was softened, i.e. weaker than in the case of the cryocooling and the compressed air cooling tests. The thickness of the coating deposit was measured in several locations of the metallographic cross-sections examined and it was found that the cryogenic cooling improved the coating material deposition efficiency by 20% as compared to the conventional, compressed air cooling. Moreover, the deposition efficiency of the ambient air cooling was 12% lower as compared to the conventional, compressed air cooling. Thus, the application of cryocooling combined with compressed air was shown to increase deposition efficiency by 32% as compared to the ambient cooling. The higher deposition efficiency associated with the cryocooling method results, also in more heat delivered to the surface because more of the hot coating material dissipates its heat to the substrate and the masking material. Thus, the cryocooling was found to preserve the flexible mask even though the mask was exposed to a larger quantity of heat than in the other two test cases.

Experimental Results:

| Cooling Method and | | | |
|---|---|---|---|
| Maximum Surface | | | Thickness Gain if |
| Temperature Reached | Coating | Coating | Conventional, |
| During Spray- | Thickness in | Thickness in | Forced Air |
| coating Cycle | Micrometers | Inches | Cooling = 100% |
| Conventional: Forced Air | 396 | 0.0156 | 0% |
| (<300° F. or 150° C.) | | | |
| Invention: LIN together | 474 | 0.0187 | 20% |
| with Forced Air | | | |
| (<300° F. or 150° C.) | | | |
| No Cooling During | 350 | 0.0138 | −12% |
| Spray-coating Cycle | | | |
| (>>575° F. or 302° C.) | | | |

1. A method for preventing the degradation of one or more mask materials during a thermal surface treatment process of a substrate comprising the steps of:
mounting at least one mask comprising one or more mask materials onto a substrate;
thermally surface treating a surface of the substrate which increases the temperature of the substrate; and
cooling the one or more mask materials with cryogenic fluid from at least one cooling means directed at the substrate.

2. The method of claim 1 further comprising the step of cooling the substrate to a temperature not exceeding the degradation temperature of the one or more mask materials adjacent to said substrate.

3. The method of claim 1, further wherein during said cooling step, said cryogenic fluid is continuously directed at said at least one mask.

4. The method of claim 1, further wherein during said cooling step, said cryogenic fluid is intermittently directed at said at least one mask.

5. The method of claim 1, further comprising the step of directing an additional coolant from an additional cooling means onto said substrate.

6. The method of claim 5, further comprising the step of moving said additional cooling means.

7. The method of claim 5, wherein said additional cooling means indirectly cools the surface of the substrate to receive the thermal surface treatment.

8. The method of claim 5, wherein said additional cooling means is an air header, a cryogenic fluid nozzle, or cryogenic fluid header.

9. The method of claim 1, further comprising the step of moving or rotating said substrate during said thermally treating surface step.

10. The method of claim 1, wherein said thermal surface treating step is performed by a thermal surface treatment means, and said method further comprising the step of moving or rotating said thermal surface treatment means during said applying step.

11. The method of claim 1, further comprising the step of moving or rotating said cooling means.

12. The method of claim 10, further comprising the step of moving or rotating said cooling means and said thermal treatment means simultaneously.

13. The method of claim 1, wherein during said thermally surface treating step, said step creates a hot spot on said substrate, and during said cooling step said cryogenic fluid is directed at the substrate at the trailing edge of said hot spot.

14. The method of claim 1, wherein said thermally surface treating step is selected from the group consisting of thermal plasma spraying, high-velocity oxy-fuel (HVOF) spraying, arc-spraying, flame spraying, chemical vapor depositing, physical vapor depositing, flash-lamp treating, ultraviolet lamp treating, and radiative curing.

15. The method of claim 1, further comprising prior to said mounting step, the step of determining a thickness for the at least one mask to mount onto said substrate, said thickness of said at least one mask being greater than the depth of degradation of the mask caused by a single pass of the thermal treatment over the mask.

16. The method of claim 1, further comprising prior to said mounting step, the step of determining a thickness for the at least one mask to mount onto said substrate, said thickness of said at least one mask being inversely proportional to a time performing said cooling step on said at least one mask as a fraction of time spent performing said applying step on the substrate.

17. A method of thermally surface treating a substrate said method comprising:
moving or rotating a cryogenic fluid nozzle simultaneously with a thermal treatment means;
thermally surface treating the substrate with said thermal treatment means to create a hot spot;
cooling with cryogenic fluid directed from said nozzle a trailing edge of the hot spot;
and cooling said substrate by an additional cooling means.

18. An apparatus for performing the method of claim 1 comprising a thermal treatment means and at least one cooling means.

19. An apparatus for performing the method of claim 17 comprising a thermal treatment means and at least one cooling means.
